(19) United States
(12) Patent Application Publication
(10) Pub. No.: US 2023/0411240 A1
(43) Pub. Date: Dec. 21, 2023

(54) SEMICONDUCTOR APPARATUS AND METHOD FOR MANUFACTURING THE SEMICONDUCTOR APPARATUS

(71) Applicant: Mitsubishi Electric Corporation, Tokyo (JP)

(72) Inventor: Kazuki TAKAKURA, Tokyo (JP)

(73) Assignee: Mitsubishi Electric Corporation, Tokyo (JP)

(21) Appl. No.: 18/148,665

(22) Filed: Dec. 30, 2022

(30) Foreign Application Priority Data
Jun. 20, 2022 (JP) 2022-098831

(51) Int. Cl. H01L 23/42; H01L 21/48

(52) U.S. Cl. CPC H01L 23/42; H01L 21/4882

(57) ABSTRACT

A semiconductor manufacturing apparatus according to the present disclosure is configured such that a first resin heat dissipation material directly or indirectly contacts a heat dissipation surface of a semiconductor device having a low heat dissipation property. The first resin heat dissipation material has an opening that exposes a heat dissipation fin above a heat dissipation surface of a semiconductor device other than the semiconductor device that directly or indirectly contacts the first resin heat dissipation material. The heat dissipation fin is configured to pass through the opening of the first resin heat dissipation material and directly or indirectly contact the heat dissipation surface of the semiconductor device other than the semiconductor device that directly or indirectly contacts the first resin heat dissipation material.

### BACKGROUND OF THE INVENTION

### Field

The present disclosure relates to a semiconductor apparatus and a method for manufacturing the semiconductor apparatus, and particularly to a semiconductor apparatus favorable as a power semiconductor apparatus and a method for manufacturing the same.

### Background

In a semiconductor apparatus in which a plurality of semiconductor devices are mounted on the same substrate, each of the semiconductor devices needs to be brought into contact with a cooling component such as a heat dissipation fin to cool heat generated from the semiconductor device. However, the semiconductor devices are of types such as an insertion type, and a surface mounted type, and differ in height in not a few cases. The surface mounted type semiconductor device is lower in height than other mounted type semiconductor devices, and may have no screw attachment hole. Accordingly, it is particularly difficult to bring the surface mounted type semiconductor device into contact with the cooling component. When the semiconductor devices thus differ in height, a method for bringing the semiconductor devices into contact with the cooling component using, for example, a spacer for height matching is used. Alternatively, another method is disclosed in JP 2020-198347 A. JP 2020-198347 A discloses a method for bringing each of semiconductor devices and a heat dissipation fin into contact with each other by processing the heat dissipation fin itself to match the height of the semiconductor device. This method makes it possible to efficiently cool each of the semiconductor devices.

However, in the conventional technique, a heat dissipation path for cooling the plurality of semiconductor devices that generate heat has been set only in the heat dissipation fin. Accordingly, the heat dissipation fin needs to be processed for each of the semiconductor devices depending on the height of each semiconductor device, thereby making it difficult to implement a heat dissipation design suitable for each of the semiconductor apparatuses.

### SUMMARY

The present disclosure has been made to solve the above-described problem, and has as its first object to provide a semiconductor apparatus capable of implementing, even when a plurality of semiconductor devices that generate heat differ in height, a heat dissipation design suitable for each of the semiconductor apparatuses.

The present disclosure has been made to solve the above-described problem, and has as its second object to provide a method for manufacturing a semiconductor apparatus capable of implementing, even when a plurality of semiconductor devices that generate heat differ in height, a heat dissipation design suitable for each of the semiconductor apparatuses.

The features and advantages of the present disclosure may be summarized as follows.

According to one aspect of the present disclosure, a semiconductor apparatus includes: a plurality of semiconductor devices that differ in height, a substrate to which the plurality of semiconductor devices are attached, a first resin heat dissipation material having one surface facing a surface of each of the semiconductor devices and a heat dissipation fin to be thermally coupled to the first resin heat dissipation material on a surface of the first resin heat dissipation material opposite to the surface facing the semiconductor devices, wherein the plurality of semiconductor devices include at least one semiconductor device having a low heat generation property and at least one semiconductor device having a high heat generation property, the first resin heat dissipation material is configured to directly or indirectly contact a heat dissipation surface of the semiconductor device having the low heat generation property, and has an opening that exposes the heat dissipation fin above a heat dissipation surface of the semiconductor device other than the semiconductor device that directly or indirectly contacts the first resin heat dissipation material, and the heat dissipation fin is configured to pass through the opening of the first resin heat dissipation material, and directly or indirectly contact the heat dissipation surface of the semiconductor device other than the semiconductor device that directly or indirectly contacts the first resin heat dissipation material.

According to another aspect of the present disclosure, a method for manufacturing a semiconductor apparatus includes: a step of producing a substrate to which a plurality of semiconductor devices are attached, a step of producing a first resin heat dissipation material arranged to face a surface of each of the semiconductor devices attached to the substrate, a step of producing a heat dissipation fin, a step of producing a second resin heat dissipation material arranged on a surface of the substrate opposite to the first resin heat dissipation material, a first set member production step of fixing the heat dissipation fin to a surface of the first resin heat dissipation material opposite to a surface of the first resin heat dissipation material facing the semiconductor device such that the heat dissipation fin is thermally coupled to the first resin heat dissipation material, to produce a first set member, a second set member production step of fixing the substrate and the second resin heat dissipation material to each other to produce a second set member, and a step of fixing the first set member and the second set member to each other.

Other and further objects, features and advantages of the disclosure will appear more fully from the following description.

### BRIEF DESCRIPTION OF DRAWINGS

FIG. 1 is a cross-sectional view of a semiconductor apparatus according to a first embodiment of the present disclosure.

FIG. 2 is a cross-sectional view of a semiconductor apparatus according to a second embodiment of the present disclosure.

FIG. 3 is a cross-sectional view of a semiconductor apparatus according to a third embodiment of the present disclosure.

FIG. 4 is a cross-sectional view of a semiconductor apparatus according to a fourth embodiment of the present disclosure.

FIG. 5 is a cross-sectional view of a semiconductor apparatus according to a fifth embodiment of the present disclosure.

FIG. 6 is a cross-sectional view of a semiconductor apparatus according to a sixth embodiment of the present disclosure.

FIG. 7 is a cross-sectional view of a semiconductor apparatus according to a seventh embodiment of the present disclosure.

FIG. 8 is a cross-sectional view of a semiconductor apparatus according to an eighth embodiment of the present disclosure.

FIG. 9 is a cross-sectional view of a semiconductor apparatus according to a ninth embodiment of the present disclosure.

FIG. 10 is a cross-sectional view of a semiconductor apparatus according to a tenth embodiment of the present disclosure.

FIG. 11 is a cross-sectional view of a semiconductor apparatus according to an eleventh embodiment of the present disclosure.

FIG. 12 is a cross-sectional view of a semiconductor apparatus according to a twelfth embodiment of the present disclosure.

FIG. 13 is a cross-sectional view of a semiconductor apparatus according to a thirteenth embodiment of the present disclosure.

FIG. 14 is a cross-sectional view of a semiconductor apparatus according to a fourteenth embodiment of the present disclosure.

### DESCRIPTION OF EMBODIMENTS

### First Embodiment

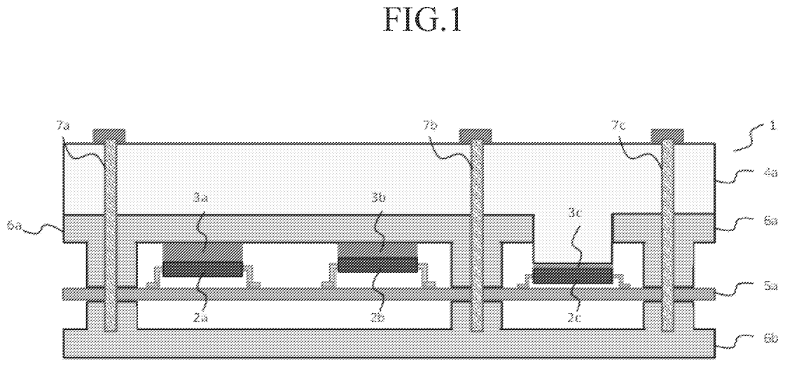

FIG. 1 is a cross-sectional view of a semiconductor apparatus according to a first embodiment of the present disclosure. The semiconductor apparatus 1 includes a substrate 5a. In the semiconductor apparatus 1, semiconductor devices 2a, 2b, and 2c are mounted on the substrate 5a. Respective terminal shapes of the semiconductor devices 2a, 2b, and 2c are not limited, although they may be of types such as a substrate insertion type and a surface mounted type. The semiconductor apparatus 1 includes a heat dissipation fin 4a for cooling above the semiconductor devices 2a, 2b, and 2c. A surface of the substrate 5a on the heat dissipation fin 4a side is a first main surface of the substrate 5a. A surface of the substrate 5a on the opposite side to the first main surface is a second main surface of the substrate 5a.

Further, the semiconductor apparatus 1 includes housings 6a and 6b, respectively, on the first main surface side and the second main surface side of the substrate 5a. The housings 6a and 6b are mounted to surround the substrate 5a and the semiconductor devices 2a, 2b, and 2c from the first main surface side and the second main surface side of the substrate 5a, respectively. The heat dissipation fin 4a, the substrate 5a, and the housings 6a and 6b are fixed to one another with each of screws 7a, 7b, and 7c. A direction in which the screws 7a, 7b, and 7c are fastened is changeable from the heat dissipation fin 4a side or the housing 6b side. Alternatively, if each of the semiconductor devices 2a, 2b, and 2c has a screw attachment hole, the screw attachment hole of the semiconductor device may be used. The heat dissipation fin 4a and the housing 6a need not be in direct contact with each other, but may be thermally coupled to each other.

In the present and subsequent embodiments, it is assumed that the semiconductor devices 2a, 2b, and 2c have different heights and heat generation properties. In the present and subsequent embodiments, it is assumed that the semiconductor device that contacts the housing 6a is a semiconductor device having a low heat generation property, and in addition, the semiconductor device that contacts the heat dissipation fin 4a is a semiconductor device having a high heat generation property, unless otherwise specified. The number and the arrangement order of the semiconductor devices 2a, 2b, and 2c are examples, and are not intended to limit the technical scope of the present disclosure.

Heat dissipation surfaces of the semiconductor devices 2a and 2b each having a low heat generation property are in indirect contact with the housing 6a with heat dissipation buffer materials 3a and 3b interposed therebetween. The semiconductor devices 2a and 2b each having a low heat generation property are brought into contact with the housing 6a, whereby the semiconductor devices 2a and 2b each having a low heat generation property can be made to dissipate heat to the housing 6a.

The semiconductor devices 2a and 2b each having a low heat generation property can be brought into indirect contact with the housing 6a, when the thicknesses of the heat dissipation buffer materials 3a and 3b are adjusted. Even if the semiconductor devices 2a and 2b each having a low heat generation property differ in height, each of the semiconductor devices 2a and 2b can be brought into indirect contact with the housing 6a when the heat dissipation buffer materials 3a and 3b having different thicknesses are respectively inserted into the semiconductor devices 2a and 2b.

The heat dissipation buffer materials 3a and 3b may not be used when the heat dissipation buffer materials 3a and 3b are not required in heat dissipation designs for the semiconductor devices 2a and 2b. Even if the heat dissipation buffer materials 3a and 3b are not used, the semiconductor devices 2a and 2b and the housing 6a may directly contact each other. A portion to which each of the heat dissipation buffer materials 3a, 3b, and 3c is applied may be the entire portion or may be only a specific part of the portion.

Although an example of each of the dissipation buffer materials 3a, 3b, and 3c may be a grease or a heat dissipation sheet, or a thermally conductive double-faced tape, the type of the heat dissipation buffer material is not limited if the thickness thereof can be adjusted.

Although an example of each of the housings 6a and 6b may be plastic or resin having an insulation property, a material or a material quality of the housing is not limited if the housing has an insulation property and has a high heat dissipation property. A casing covering the semiconductor devices 2a, 2b, and 2c may be used as each of the housings 6a and 6b if it has an insulation property and has a high heat dissipation property.

The housing 6a on the first main surface side has an opening above the semiconductor device 2c having a high heat generation property. The heat dissipation fin 4a is exposed in the opening of the housing 6a. The heat dissipation fin 4a has a projection passing through the opening of the housing 6a. The height of the projection is adjusted depending on the height of the semiconductor device 2c. That is, the height of the projection is adjusted such that semiconductor device 2c having a high heat generation property indirectly contacts the projection of the heat dissipation fin 4a with the heat dissipation buffer material 3c interposed therebetween. This makes it possible to make the semiconductor device 2c having a high heat generation property dissipate heat to the heat dissipation fin 4a. The heat dissipation buffer material 3c may not also be necessarily used, like the heat dissipation buffer materials 3a and 3b. When the heat dissipation buffer material 3c is not used, the semiconductor device 2c and the heat dissipation fin 4a may be in direct contact with each other.

In the present embodiment, a configuration for bringing each of the semiconductor devices 2a, 2b, and 2c having different heights into contact with the heat dissipation fin 4a or the housing 6a has been described. This configuration makes it possible to set a heat dissipation path to the heat dissipation fin 4a or a heat dissipation path to the housing 6a for each of the semiconductor devices 2a, 2b, and 2c that generate heat. When the heat dissipation paths are separately used, a heat dissipation design suitable for a heat generation property of each of the semiconductor devices 2a, 2b, and 2c or a usage condition of the semiconductor apparatus 1 can be implemented.

The present embodiment has described adjusting the thicknesses of the heat dissipation buffer materials 3a and 3b to bring the semiconductor devices 2a and 2b into contact with the housing 6a. A method for adjusting the heights of the semiconductor devices 2a and 2b by changing the thicknesses of the heat dissipation buffer materials 3a and 3b is easier than processing of the heat dissipation fin 4a itself made of a metal or the like. Therefore, the present embodiment has an advantage that when the heat dissipation path for each of the semiconductor devices 2a and 2b is set as the heat dissipation path to the housing 6a, the processing of the heat dissipation fin 4a for adjusting the height of the semiconductor device can be reduced.

In the present embodiment, a case where the semiconductor device 2c that contacts the heat dissipation fin 4a is a semiconductor device having a high heat generation property has been described. However, the semiconductor device 2c that contacts the heat dissipation fin 4a may be a semiconductor device having a low heat generation property, and a design suitable for the usage condition of the semiconductor apparatus 1 may be made. This point is common in all embodiments, described below.

On the other hand, the semiconductor device having a high heat generation property is made to dissipate heat to the heat dissipation fin 4a more favorably than to the housing 6a. This is because the heat dissipation fin 4a made of a metal or the like is more excellent in cooling property than the housing 6a made of plastic or the like.

The semiconductor devices 2a, 2b, and 2c are not limited to those formed of silicon, but may be those formed of a wide bandgap semiconductor having a larger band gap than that of silicon. An example of the wide bandgap semiconductor is silicon carbide, a gallium nitride-based material, or diamond. The semiconductor device formed of the wide bandgap semiconductor can be miniaturized because it is high in withstand voltage and permissible current density. When the miniaturized semiconductor device is used, a semiconductor apparatus 1 into which the semiconductor device is incorporated can also be miniaturized and highly integrated. Since the heat resistance of the semiconductor device is high, the heat dissipation fin 4a as a heat sink can be miniaturized, and a water cooling section can be air-cooled. Therefore, the semiconductor apparatus 1 can be further miniaturized. The power loss of the semiconductor device is low so that the semiconductor device is high in efficiency. Accordingly, the semiconductor apparatus 1 can be made highly efficient. All the semiconductor devices 2a, 2b, and 2c are each desirably formed of a wide bandgap semiconductor. However, any one of the semiconductor devices may be formed of a wide bandgap semiconductor, thereby obtaining an effect described in the present embodiment. This point is also common in all the embodiments, described below.

Description of Correspondence Relationship with Terms Used in Claims: a heat dissipation material arranged on the first main surface side of the substrate 5a and favorable for making a semiconductor device having a low heat generation property dissipate heat, described in the present embodiment, is named a first resin heat dissipation material. Similarly, a heat dissipation material arranged on the second main surface side of the substrate 5a and favorable for making a semiconductor device having a low heat generation property dissipate heat is named a second resin heat dissipation material. That is, in the present embodiment, the housing 6a is a first resin heat dissipation material, and the housing 6b is a second resin heat dissipation material. These points are also common in the embodiments, described below, unless otherwise specified.

### Second Embodiment

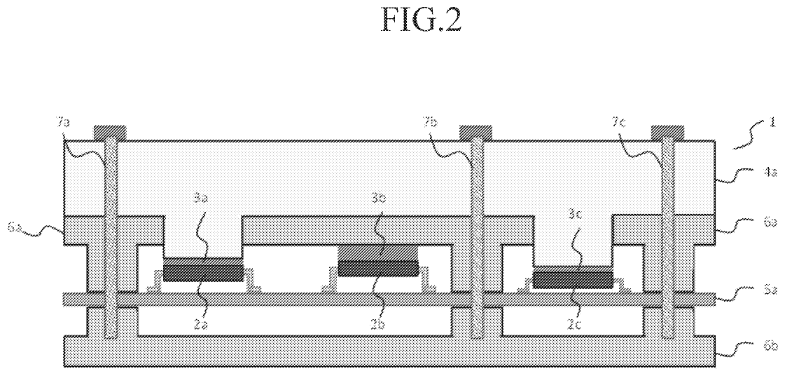

FIG. 2 is a cross-sectional view of a semiconductor apparatus according to a second embodiment of the present disclosure. A semiconductor apparatus 1 according to the present embodiment has a structure including a plurality of openings of a housing 6a and a plurality of projections of a heat dissipation fin 4a, described in the first embodiment. Specifically, the housing 6a on the first main surface side has the openings above semiconductor devices 2a and 2c. The heat dissipation fin 4a has a shape in which the projections protrude toward the first main surface side in the openings above the semiconductor devices 2a and 2c. The heat dissipation fin 4a is thus provided with the plurality of projections, whereby each of the plurality of semiconductor devices 2a and 2c can be brought into contact with the heat dissipation fin 4a. As a result, the plurality of semiconductor devices 2a and 2c can be made to dissipate heat to the heat dissipation fin 4a. The present embodiment is effective in cases such as a case where the semiconductor devices 2a and 2c are each a semiconductor device having a high heat generation property and are desired to dissipate heat to the heat dissipation fin 4a.

### Third Embodiment

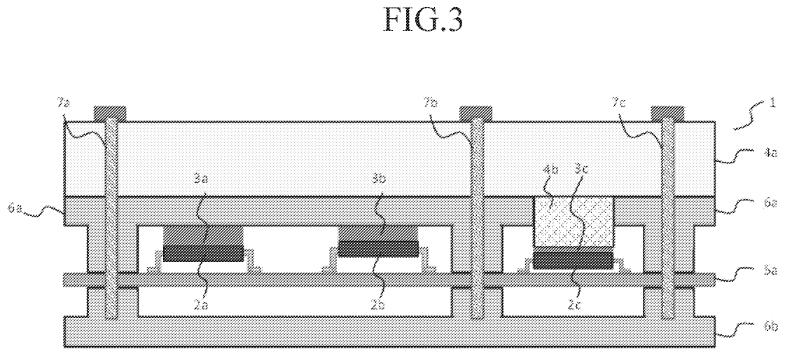

FIG. 3 is a cross-sectional view of a semiconductor apparatus according to a third embodiment of the present disclosure. A heat dissipation fin 4a in a semiconductor apparatus 1 is a flat heat dissipation fin having no projection. A sub-heat dissipation fin 4b is embedded in an opening of a housing 6a, and the sub-heat dissipation fin 4b is in contact with the heat dissipation fin 4a. The sub-heat dissipation fin 4b passes through the opening of the housing 6a, and contacts a semiconductor device 2c with a heat dissipation buffer material 3c interposed therebetween. The heat dissipation fin 4a with which a projection is not thus integrally formed and a main body of which is flat is used, and the sub-heat dissipation fin 4b is produced as a separate member, thereby making processing easy. The heat dissipation fin 4a can also be shared between the semiconductor device 2c and other semiconductor apparatuses.

Although an example of a method for fixing the sub-heat dissipation fin 4b and the housing 6a may be an adhesive, the method is not limited if the sub-heat dissipation fin 4b and the housing 6a are fixed and thermally coupled to each other. The size or the shape of the sub-heat dissipation fin 4b is not limited if the sub-heat dissipation fin 4b can be in contact with the semiconductor device 2c and the heat dissipation fin 4a.

### Fourth Embodiment

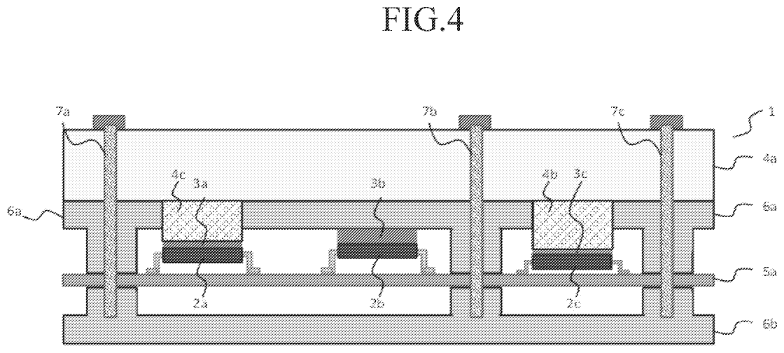

FIG. 4 is a cross-sectional view of a semiconductor apparatus according to a fourth embodiment of the present disclosure. A semiconductor apparatus 1 according to the present embodiment has a structure including a plurality of sub-heat dissipation fins illustrated in the third embodiment. The semiconductor apparatus 1 thus includes a plurality of sub-heat dissipation fins 4b and 4c, whereby a plurality of semiconductor devices 2a and 2c can be made to dissipate heat to a heat dissipation fin 4a via the sub-heat dissipation fins 4c and 4b, respectively. For example, the present embodiment is effective in cases such as a case where the semiconductor devices 2a and 2c are each a semiconductor device having a high heat generation property and are desired to dissipate heat to the heat dissipation fin 4a. If the respective sizes of the sub-heat dissipation fin 4b and the sub-heat dissipation fin 4c are the same, these components can be shared.

### Fifth Embodiment

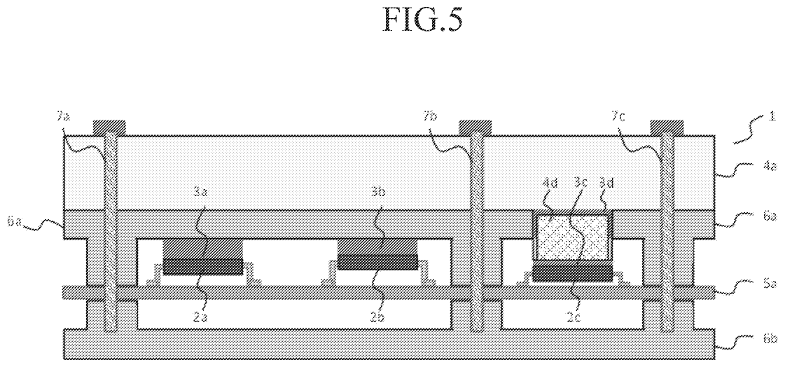

FIG. 5 is a cross-sectional view of a semiconductor apparatus according to a fifth embodiment of the present disclosure. In the present embodiment, a flat heat dissipation fin 4a having no projection is used, like in the third embodiment. A sub-heat dissipation fin 4d is embedded in an opening of a housing 6a, like in the third embodiment. The sub-heat dissipation fin 4d is embedded in the housing 6a and the heat dissipation fin 4a with a heat dissipation buffer material 3d interposed therebetween, unlike in the third embodiment. When the heat dissipation buffer material 3d is thus used, even if there is a gap between the sub-heat dissipation fin 4d and the housing 6a, the gap can be filled by adjusting the amount and the thickness of the heat dissipation buffer material 3d. That is, these components need not be closely processed such that the sub-heat dissipation fin 4d is fitted in the opening of the housing 6a.

### Sixth Embodiment

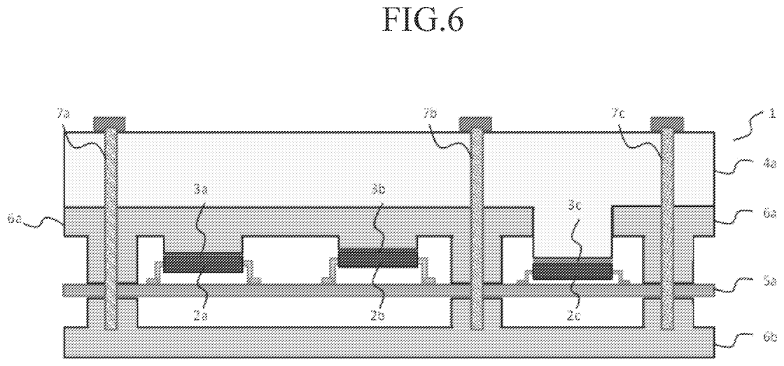

FIG. 6 is a cross-sectional view of a semiconductor apparatus according to a sixth embodiment of the present disclosure. A housing 6a in a semiconductor apparatus 1 has a plurality of projections. The heights of the projections are adjusted depending on the heights of semiconductor devices 2a and 2b. That is, the projections of the housing 6a are adjusted such that the semiconductor devices 2a and 2b indirectly contact the projections with heat dissipation buffer materials 3a and 3b interposed therebetween. The projections are thus formed in the housing 6a, whereby the heat dissipation buffer materials 3a and 3b can be made as thin as possible. If the heat dissipation buffer materials 3a and 3b are too thick, this may cause their respective heat dissipation properties to deteriorate. In contrast, an effect of preventing such a phenomenon is expected in the present embodiment. Further, the heat dissipation buffer materials 3a and 3b having the same thickness can also be respectively inserted into the semiconductor devices 2a and 2b. If the respective thicknesses of the heat dissipation buffer materials 3a and 3b differ from each other, the respective heat dissipation properties thereof may differ depending on the thicknesses, and a heat dissipation design may be more complicated. When the heat dissipation buffer materials 3a and 3b having the same thickness are inserted, such a phenomenon can be prevented.

### Seventh Embodiment

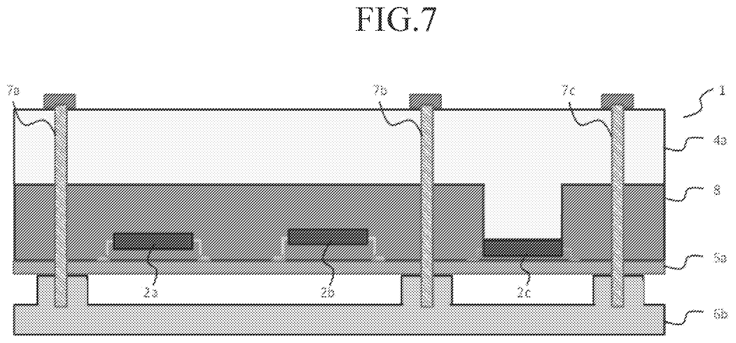

FIG. 7 is a cross-sectional view of a semiconductor apparatus according to a seventh embodiment of the present disclosure. A semiconductor apparatus 1 has a structure in which an area between the first main surface side of a substrate 5a and a heat dissipation fin 4a is filled with resin 8 having an insulation property. The semiconductor devices 2a and 2b contact the heat dissipation fin 4a with the resin 8 interposed therebetween. The area between the substrate 5a and the heat dissipation fin 4a is filled with the resin 8, whereby the semiconductor devices 2a and 2b can be made to dissipate heat to the heat dissipation fin 4a via the resin 8. At the same time, an insulation distance between the semiconductor devices or from a peripheral component can also be ensured. The semiconductor devices 2a and 2b that contact the resin 8 are each favorably a semiconductor device having a low heat generation property. On the other hand, the semiconductor device having a high heat generation property is preferably brought into contact with a projection of the heat dissipation fin 4a and made to efficiently dissipate heat. That is, a state of a semiconductor device 2c is preferable.

As a modification to the present embodiment, all semiconductor devices 2a, 2b, and 2c may be made to dissipate heat to a heat dissipation fin 4a via resin 8 without a projection being formed in the heat dissipation fin 4a. An example of the modification is a modification effective in cases such as a case where the semiconductor device 2c need not be efficiently cooled. An area between the second main surface side of a substrate 5a and a housing 6b may be filled with the resin 8.

Description of Correspondence Relationship with Terms Used in Claims: in the present embodiment, the resin 8 is a first resin heat dissipation material, and the housing 6b is a second resin heat dissipation material.

### Eighth Embodiment

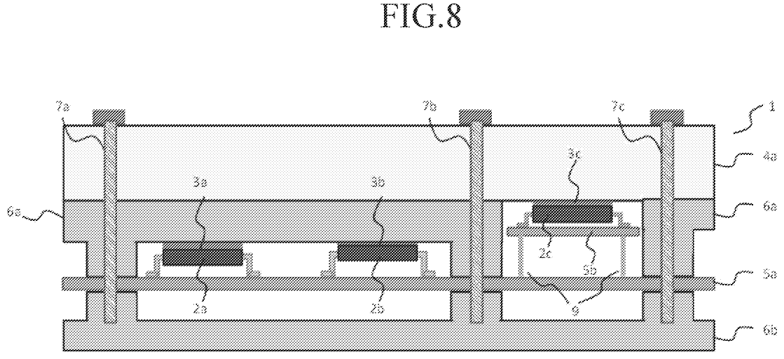

FIG. 8 is a cross-sectional view of a semiconductor apparatus according to an eighth embodiment of the present disclosure. In a semiconductor apparatus 1, a second substrate 5b is loaded on the first main surface side of a substrate 5a. The substrate 5a and the second substrate 5b are electrically connected to each other by a connection pin 9. If the connection pin 9 can electrically connect the substrate 5a and the second substrate 5b to each other, the type or the material quality thereof is not limited. A semiconductor device 2c is mounted on a first main surface of the second substrate 5b. The semiconductor device 2c contacts a heat dissipation fin 4a with a heat dissipation buffer material 3c interposed therebetween. The height of the second substrate 5b is thus adjusted by the connection pin 9, thereby eliminating the need to form a projection in the heat dissipation fin 4a.

Description of Correspondence Relationship with Terms Used in Claims: the semiconductor device 2c mounted on the second substrate 5b, described in the present embodiment, is named a second mounted semiconductor device.

### Ninth Embodiment

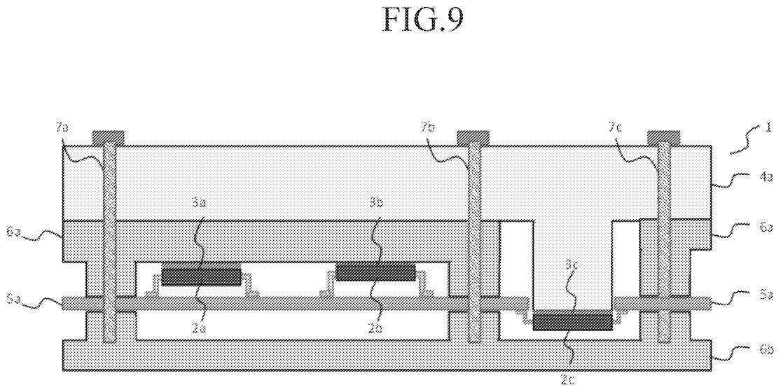

FIG. 9 is a cross-sectional view of a semiconductor apparatus according to a ninth embodiment of the present disclosure. In a semiconductor apparatus 1, a semiconductor device 2c is mounted on a second main surface of a substrate 5a. The substrate 5a is provided with an opening to expose a rear surface of the semiconductor device 2c. When the substrate 5a is provided with the opening, the rear surface of the semiconductor device 2c and a projection of a heat dissipation fin 4a can contact each other with a heat dissipation buffer material 3c interposed therebetween. That is, even if the semiconductor device 2c is not mounted on a first main surface, the semiconductor device 2c can be cooled by the heat dissipation fin 4a on the first main surface side.

In the present embodiment, a configuration in which the semiconductor device 2c mounted on the second main surface is brought into direct or indirect contact with the heat dissipation fin 4a has been described. However, when the semiconductor device 2c needs not to be cooled by the heat dissipation fin 4a, the substrate 5a needs not to be provided with an opening. That is, the semiconductor device 2c may be brought into direct or indirect contact with a housing 6b.

Description of Correspondence Relationship with Terms Used in Claims: the semiconductor device 2c mounted on the second main surface of the substrate 5a and having the opening in the substrate 5a, described in the present embodiment, is named a rear surface mounted semiconductor device.

### Tenth Embodiment

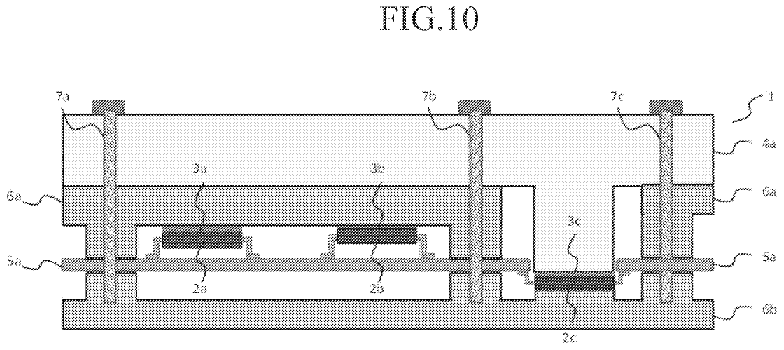

FIG. 10 is a cross-sectional view of a semiconductor apparatus according to a tenth embodiment of the present disclosure. In the present embodiment, a semiconductor apparatus 1 includes a semiconductor device 2c mounted on a second main surface, like in the ninth embodiment. The semiconductor apparatus 1 has a structure in which a rear surface of the semiconductor device 2c contacts a projection of a heat dissipation fin 4a, like in the ninth embodiment. In addition, in the present embodiment, a housing 6b on the second main surface side also has a projection, and contacts a surface of the semiconductor device 2c. That is, the semiconductor device 2c is sandwiched between the heat dissipation fin 4a and the housing 6b, and is made to dissipate heat to both the heat dissipation fin 4a and the housing 6b. This makes it possible to more enhance a heat dissipation effect.

As a modification to the present embodiment, each of semiconductor devices 2a and 2b loaded on a first main surface may be brought into contact with a projection of the housing 6b by providing a substrate 5a with an opening to expose a rear surface of the semiconductor device.

### Eleventh Embodiment

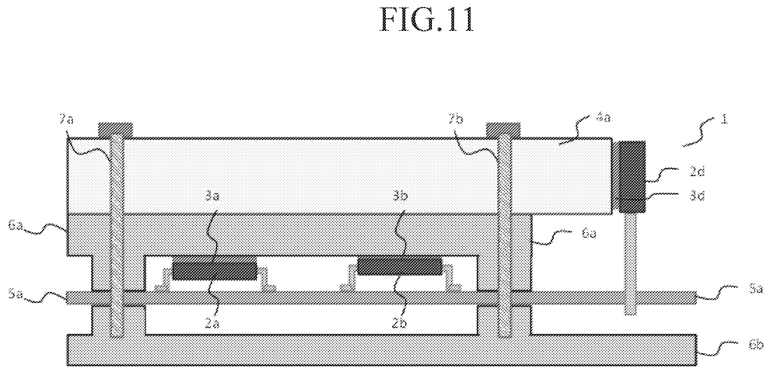

FIG. 11 is a cross-sectional view of a semiconductor apparatus according to an eleventh embodiment of the present disclosure. A semiconductor apparatus 1 includes a semiconductor device 2d having heat dissipation surfaces on its side surfaces. An example of a semiconductor device having heat dissipation surfaces on its side surfaces is a discrete-type semiconductor device. The semiconductor device 2d is mounted on a first main surface of a substrate 5a. The semiconductor device 2d and a heat dissipation fin 4a contact each other by a parallel heat dissipation surface of the heat dissipation fin 4a. The parallel heat dissipation surface of the heat dissipation fin 4a is a surface of the heat dissipation fin 4a in a parallel relationship to the side surface of the semiconductor device 2d with the semiconductor device 2d mounted on the first main surface of the substrate 5a. The semiconductor device 2d having the heat dissipation surfaces on the side surfaces is thus brought into contact with the parallel heat dissipation surface of the heat dissipation fin 4a, thereby making it easy for other semiconductor devices to match the height. The entire side surface of the semiconductor device 2d needs not to be brought into contact with the heat dissipation fin 4a but only a part of the semiconductor device 2d may be brought into contact therewith depending on the heat generation property of the semiconductor device 2d.

As a modification to the present embodiment, when the heat generation property of a semiconductor device 2d is low, the semiconductor device 2d may be brought into contact with a parallel heat dissipation surface of a housing 6a and made to dissipate heat to the housing 6a.

Description of Correspondence Relationship with Terms Used in Claims: the semiconductor device 2d having the heat dissipation surface on the side surface, described in the present embodiment, is named a side surface heat dissipation semiconductor device.

### Twelfth Embodiment

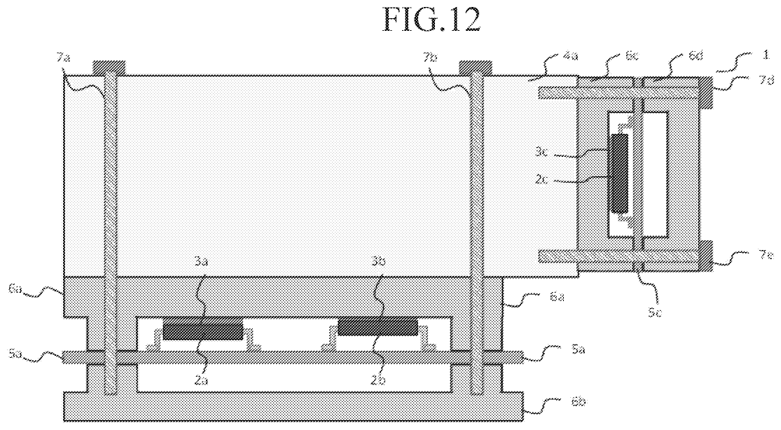

FIG. 12 is a cross-sectional view of a semiconductor apparatus according to a twelfth embodiment of the present disclosure. A semiconductor apparatus 1 further includes a third substrate 5c. A substrate 5a and the third substrate 5c may be electrically connected to each other via a connection pin or a connector wiring, for example. A semiconductor device 2c is mounted on a first main surface of the third substrate 5c. The first main surface of the third substrate 5c is a surface of the third substrate 5c on the heat dissipation fin 4a side. In addition, the semiconductor apparatus 1 further includes housings 6c and 6d. The housings 6c and 6d are mounted to surround the third substrate 5c and the semiconductor device 2c from the first main surface side of the third substrate 5c and the opposite side thereto. The semiconductor device 2c is in contact with a surface, other than a surface that the housing 6a contacts, among surfaces of the heat dissipation fin 4a with these members interposed therebetween. When the third substrate 5c, the semiconductor device 2c, the housings 6c and 6d, and the like, are thus further added, to produce a mount member, the semiconductor device 2c loaded on the mount member can be brought into contact with the desired surface of the heat dissipation fin 4a.

As a modification to the present embodiment, a heat dissipation fin 4a and a semiconductor device 2c may be in direct or indirect contact with each other by providing a housing 6c with an opening and forming a projection in a heat dissipation fin 4a.

Description of Correspondence Relationship with Terms Used in Claims: a heat dissipation material arranged on the first main surface side of the third substrate 5c and favorable for making a semiconductor device having a low heat generation property dissipate heat, described in the present embodiment, is named a third resin heat dissipation material. That is, in the present embodiment, the housing 6c is the third resin heat dissipation material. The present embodiment is an example, and the third resin heat dissipation material is not limited to a housing.

### Thirteenth Embodiment

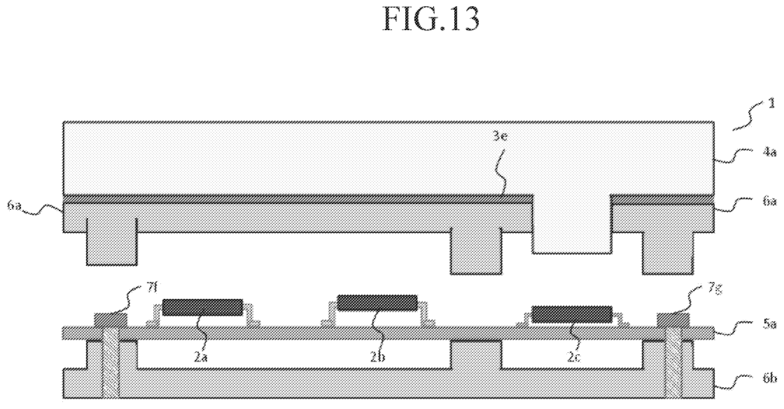

FIG. 13 is a cross-sectional view of a semiconductor apparatus according to a thirteenth embodiment of the present disclosure. In a semiconductor apparatus 1, a housing 6b and a substrate 5a are fastened to each other with screws 7f and 7g. A housing 6a and a heat dissipation fin 4a are fixed and bonded to each other by a heat dissipation buffer material 3e. The housing 6a and the heat dissipation fin 4a may be fixed to each other by screw fastening if difficult to fix by only the heat dissipation buffer material 3e. If components have been previously fixed to each other, like in the present embodiment, the components are more easily assembled than when the heat dissipation fin 4a, the substrate 5a, and the housings 6a and 6b are simultaneously fixed to one another with screws, like in the first embodiment. A screw fastening position and a method for fixing the heat dissipation fin 4a, the substrate 5a, and the housings 6a and 6b to one another are not limited. The fixing method can be determined depending on the assembly of the semiconductor apparatus 1 or the number of semiconductor devices.

A method for manufacturing a semiconductor apparatus 1 according to the present embodiment is as follows. First, a substrate 5a to which a plurality of semiconductor devices 2a, 2b, and 2c are attached is produced. Then, housings 6a and 6b and a heat dissipation fin 4a are produced. Then, a first set member in which the housing 6a and the heat dissipation fin 4a are fixed to each other by a heat dissipation buffer material 3e is produced. Further, a second set member in which the substrate 5a and the housing 6b are fixed to each other with screws 7f and 7g is produced. Finally, the first set member and the second set member are fixed to each other, to complete the semiconductor apparatus 1. The semiconductor apparatus 1 becomes easy to manufacture by following such a process procedure.

Description of Correspondence Relationship with Terms Used in Claims: a step for producing the first set member, described in the present embodiment, is named a first set member production step. Similarly, a step for producing the second set member is named a second set member production step.

### Fourteenth Embodiment

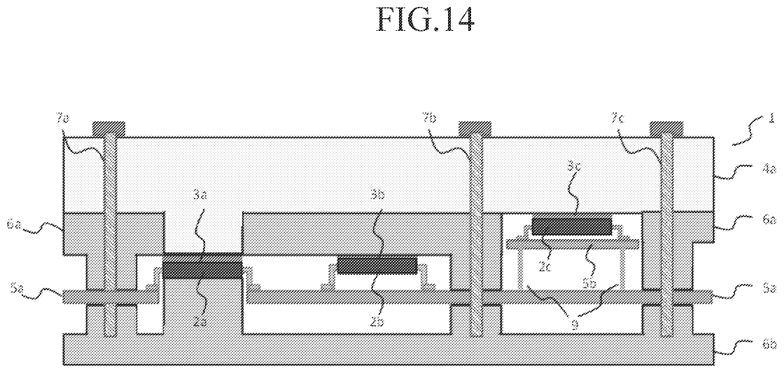

FIG. 14 is a cross-sectional view of a semiconductor apparatus according to a fourteenth embodiment of the present disclosure. A semiconductor apparatus 1 is characterized by a structure using a plurality of forms described in the first to thirteenth embodiments in combination. For example, the semiconductor apparatus 1 illustrated in FIG. 14 has a structure obtained by combining the first, ninth, and tenth embodiments. A heat dissipation fin 4a and a housing 6b each have a projection, and a semiconductor device 2a is sandwiched therebetween. The semiconductor apparatus 1 includes a second substrate 5b the height of which has been adjusted by a connection pin 9 on a first main surface of a substrate 5a. The substrate 5a and the second substrate 5b are electrically connected to each other. A semiconductor device 2c is mounted on the second substrate 5b. The semiconductor device 2c is in contact with the heat dissipation fin 4a with a heat dissipation buffer material 3c interposed therebetween. Thus, two or more embodiments to be combined may be freely combined. Semiconductor devices 2a, 2b, and 2c are made to dissipate heat to housings 6a and 6b or a heat dissipation fin 4a or resin 8 via heat dissipation buffer materials 3a, 3b, and 3c, respectively. Alternatively, semiconductor devices 2a, 2b, and 2c may each have a plurality of heat dissipation paths simultaneously. The first to thirteenth embodiments are thus used in combination, thereby making it possible to implement an optimum heat dissipation and structure design conforming to a usage environment of a semiconductor apparatus 1.

As has been explained thus far, a first aspect of the present disclosure makes it possible to provide a semiconductor apparatus capable of implementing, even when a plurality of semiconductor devices that generate heat differ in height, a heat dissipation design suitable for each of the semiconductor apparatuses.

Moreover, another aspect of the present disclosure makes it possible to provide a method for manufacturing a semiconductor apparatus capable of implementing, even when a plurality of semiconductor devices that generate heat differ in height, a heat dissipation design suitable for each of the semiconductor apparatuses.

Obviously many modifications and variations of the present disclosure are possible in the light of the above teachings. It is therefore to be understood that within the scope of the appended claims the invention may be practiced otherwise than as specifically described.

The entire disclosure of a Japanese Patent Application No. 2022-98831, filed on Jun. 20, 2022 including specification, claims, drawings and summary, on which the Convention priority of the present application is based, are incorporated herein by reference in its entirety.

1. A semiconductor apparatus comprising:
a plurality of semiconductor devices that differ in height;
a substrate to which the plurality of semiconductor devices are attached;
a first resin heat dissipation material having one surface facing a surface of each of the semiconductor devices; and
a heat dissipation fin to be thermally coupled to the first resin heat dissipation material on a surface of the first resin heat dissipation material opposite to the surface facing the semiconductor devices, wherein
the plurality of semiconductor devices include
at least one semiconductor device having a low heat generation property and at least one semiconductor device having a high heat generation property,
the first resin heat dissipation material is configured to
directly or indirectly contact a heat dissipation surface of the semiconductor device having the low heat generation property, and
has an opening that exposes the heat dissipation fin above a heat dissipation surface of the semiconductor device other than the semiconductor device that directly or indirectly contacts the first resin heat dissipation material, and
the heat dissipation fin is configured to
pass through the opening of the first resin heat dissipation material, and
directly or indirectly contact the heat dissipation surface of the semiconductor device other than the semiconductor device that directly or indirectly contacts the first resin heat dissipation material.

2. The semiconductor apparatus according to claim 1, further comprising
a second resin heat dissipation material facing a surface of the substrate opposite to the heat dissipation fin, wherein
the substrate has an opening that exposes a rear surface of at least one of the semiconductor devices mounted on a surface of the substrate on a heat dissipation fin side, and
the second resin heat dissipation material is configured to passes through the opening of the substrate and directly or indirectly contact the rear surface of the semiconductor device.

3. The semiconductor apparatus according to claim 1, further comprising
a second resin heat dissipation material facing a surface of the substrate opposite to the heat dissipation fin, wherein
the second resin heat dissipation material is configured to directly or indirectly contact a surface of the semiconductor device mounted on the surface of the substrate opposite to the heat dissipation fin.

4. The semiconductor apparatus according to claim 1, wherein
the semiconductor devices include a rear surface mounted semiconductor device mounted on a surface of the substrate opposite to the heat dissipation fin,
the substrate has an opening that exposes a rear surface of the rear surface mounted semiconductor device, and
the heat dissipation fin is configured to pass through the opening of the first resin heat dissipation material and the opening of the substrate, and directly or indirectly contact the rear surface of the rear surface mounted semiconductor device.

5. The semiconductor apparatus according to claim 1, wherein the first resin heat dissipation material includes a heat dissipation buffer material between the first resin heat dissipation material and the semiconductor device that indirectly contacts the first resin heat dissipation material.

6. The semiconductor apparatus according to claim 1, wherein the first resin heat dissipation material has a projection corresponding to a height of the semiconductor device that directly or indirectly contacts the first resin heat dissipation material.

7. The semiconductor apparatus according to claim 2, wherein at least one of the first resin heat dissipation material and the second resin heat dissipation material includes a heat dissipation buffer material between the at least one of the first resin heat dissipation material and the second resin heat dissipation material and the semiconductor device that indirectly contacts the at least one of the first resin heat dissipation material and the second resin heat dissipation material.

8. The semiconductor apparatus according to claim 3, wherein at least one of the first resin heat dissipation material and the second resin heat dissipation material includes a heat dissipation buffer material between the at least one of the first resin heat dissipation material and the second resin heat dissipation material and the semiconductor device that indirectly contacts the at least one of the first resin heat dissipation material and the second resin heat dissipation material.

9. The semiconductor apparatus according to claim 2, wherein at least one of the first resin heat dissipation material and the second resin heat dissipation material has a projection corresponding to a height of the semiconductor device that directly or indirectly contacts the at least one of the first resin heat dissipation material and the second resin heat dissipation material.

10. The semiconductor apparatus according to claim 3, wherein at least one of the first resin heat dissipation material and the second resin heat dissipation material has a projection corresponding to a height of the semiconductor device that directly or indirectly contacts the at least one of the first resin heat dissipation material and the second resin heat dissipation material.

11. The semiconductor apparatus according to claim 1, wherein the heat dissipation fin has a projection corresponding to a height of the semiconductor device that directly or indirectly contacts the heat dissipation fin.

12. The semiconductor apparatus according to claim 4, wherein the heat dissipation fin has a projection corresponding to a height of the semiconductor device that directly or indirectly contacts the heat dissipation fin.

13. The semiconductor apparatus according to claim 1, wherein
the heat dissipation fin includes
a main body; and
a separate member thermally coupled to the main body and passing through the opening of the first resin heat dissipation material.

14. The semiconductor apparatus according to claim 4, wherein
the heat dissipation fin includes
a main body; and
a separate member thermally coupled to the main body and passing through the opening of the first resin heat dissipation material.

15. The semiconductor apparatus according to claim 1, further comprising
a connection pin raised on a surface of the substrate on a heat dissipation fin side; and
a second substrate loaded on the heat dissipation fin side of the substrate by the connection pin, wherein
the semiconductor devices include a second mounted semiconductor device mounted on the second substrate, and
a height of the connection pin is adjusted such that the second mounted semiconductor device and the heat dissipation fin directly or indirectly contact each other.

16. The semiconductor apparatus according to claim 1, wherein
the semiconductor devices include a side surface heat dissipation semiconductor device having a heat dissipation surface on a side surface,
the heat dissipation fin has a parallel heat dissipation surface in parallel relationship to the side surface of the side surface heat dissipation semiconductor device with the side surface heat dissipation semiconductor device mounted on the substrate, and
the side surface heat dissipation semiconductor device is in direct or indirect contact with the parallel heat dissipation surface of the heat dissipation fin.

17. The semiconductor apparatus according to claim 1, further comprising amount member including
a third substrate;
a semiconductor device mounted on the third substrate, and
a third resin heat dissipation material facing a surface of the semiconductor device, wherein
the mount member is in direct or indirect contact with the heat dissipation fin on a surface other than a surface to which the first resin heat dissipation material is thermally coupled among surfaces of the heat dissipation fin.

18. The semiconductor apparatus according to claim 1, wherein the first resin heat dissipation material is a housing.

19. The semiconductor apparatus according to claim 1, wherein the first resin heat dissipation material is a filling resin.

20. The semiconductor apparatus according to claim 1, wherein at least one of the semiconductor devices is formed of a wide bandgap semiconductor.

21. A method for manufacturing a semiconductor apparatus, the method comprising:
a step of producing a substrate to which a plurality of semiconductor devices are attached;
a step of producing a first resin heat dissipation material arranged to face a surface of each of the semiconductor devices attached to the substrate;
a step of producing a heat dissipation fin;
a step of producing a second resin heat dissipation material arranged on a surface of the substrate opposite to the first resin heat dissipation material;
a first set member production step of fixing the heat dissipation fin to a surface of the first resin heat dissipation material opposite to a surface of the first resin heat dissipation material facing the semiconductor device such that the heat dissipation fin is thermally coupled to the first resin heat dissipation material, to produce a first set member;
a second set member production step of fixing the substrate and the second resin heat dissipation material to each other to produce a second set member; and
a step of fixing the first set member and the second set member to each other.
